(19) United States
(12) Patent Application Publication
(10) Pub. No.: US 2009/0112471 A1
(43) Pub. Date: Apr. 30, 2009

(54) TIME INFORMATION MANAGEMENT METHOD AND ELECTRONIC INSTRUMENT

(75) Inventor: Akifumi Hayashi, Azumino-shi, Nagano (JP)

Correspondence Address: GLOBAL IP COUNSELORS, LLP, 1233 20TH STREET, NW, SUITE 700, WASHINGTON, DC, 20036-2680, US

(73) Assignee: Seiko Epson Corporation, Tokyo (JP)

(21) Appl. No.: 12/260,352

(22) Filed: Oct. 29, 2008

(30) Foreign Application Priority Data
Oct. 30, 2007 (JP) 2007-281787

(51) Int. Cl. H03L 7/00; G01C 21/00

(52) U.S. Cl. 701/214; 331/25

(57) ABSTRACT

A time information management method includes: managing time information using an oscillation signal of a first oscillator and data relating to an actual oscillation frequency of the first oscillator; calculating an oscillation frequency difference between a second oscillator and the first oscillator; and estimating the actual oscillation frequency of the first oscillator using the calculated oscillation frequency difference and a nominal frequency of the second oscillator, and updating the data relating to the actual oscillation frequency of the first oscillator.

Japanese Patent Application No. 2007-281787 filed on Oct. 30, 2007, is hereby incorporated by reference in its entirety.

### BACKGROUND

The present invention relates to a time information management method and an electronic instrument.

The global positioning system (GPS) has been widely known as a positioning system that utilizes a satellite. The GPS has been utilized for a receiver device provided in a portable telephone, a car navigation system, or the like. A GPS receiver device acquires a GPS satellite estimated to be located in the sky over the receiver device based on satellite orbit information and time information of the receiver device. The receiver device calculates the distance (pseudo-range) between the GPS satellite and the receiver device based on the time (transmission time) when a GPS satellite signal has been transmitted from the GPS satellite and the time (reception time) when the GPS satellite signal has reached the receiver device, and locates the current position of the receiver device based on the pseudo-range.

Therefore, when the time information of the receiver device has a large error (e.g., several minutes), a situation in which the GPS satellite estimated by the receiver device to be located in the sky based on the satellite orbit information is not located in the sky may occur, whereby a long time may be required to acquire the GPS satellite. Even if an error of the time information of the receiver device is small (e.g., several hundreds of milliseconds or several seconds), since a signal is propagated at a speed of light, it is important to manage the time information of the receiver device. If the time of the receiver device is inaccurate, the located position calculated by positioning calculations undergoes a large positioning error.

As time information management technology, JP-A-2006-329739 discloses a positioning system that includes a server and a terminal, wherein the terminal corrects the time based on pulse information and transmission time information received from the server, for example.

However, the technology disclosed in JP-A-2006-329739 is proposed on the assumption that the server and the terminal are positioned close to each other to such an extent that the transmission time when the pulse information has been transmitted from the server is considered to be the same as the reception time when the terminal has received the pulse signal. Therefore, the technology disclosed in JP-A-2006-329739 cannot be applied directly to the case where the server and the terminal are positioned at a long distance. Specifically, since the terminal must be located in the communication area of the server and the distance between the server and the terminal must be constant when using the technology disclosed in JP-A-2006-329739, it is difficult to apply the technology disclosed in JP-A-2006-329739 when these conditions are not satisfied (e.g., when the terminal is located outside the communication area of the server).

### SUMMARY

According to one aspect of the invention, there is provided a time information management method comprising:

managing time information using an oscillation signal of a first oscillator and data relating to an actual oscillation frequency of the first oscillator;

calculating an oscillation frequency difference between a second oscillator and the first oscillator; and

estimating the actual oscillation frequency of the first oscillator using the calculated oscillation frequency difference and a nominal frequency of the second oscillator, and updating the data relating to the actual oscillation frequency of the first oscillator.

According to anther aspect of the invention, there is provided an electronic instrument comprising an electronic circuit, a control circuit, a first oscillator, and a second oscillator,

the electronic circuit including:

a time information management section that manages time information using an oscillation signal of the first oscillator and data relating to an actual oscillation frequency of the first oscillator;

a frequency difference calculation section that calculates an oscillation frequency difference between the first oscillator and the second oscillator; and

an estimation section that estimates the actual oscillation frequency of the first oscillator using the oscillation frequency difference calculated by the frequency difference calculation section and a nominal frequency of the second oscillator, and updates the data relating to the actual oscillation frequency of the first oscillator; and

the control circuit including an estimation execution control section that controls execution of the estimation by the estimation section.

### BRIEF DESCRIPTION OF THE DRAWINGS

FIG. 1 is a view illustrative of the principle of estimating an RTC actual frequency.

FIG. 2 is a block diagram showing the functional configuration of a portable telephone.

FIG. 3 is a view showing an example of data stored in a ROM of a baseband process circuit section.

FIG. 4 is a view showing an example of data stored in a RAM of a baseband process circuit section.

FIG. 5 is a view showing a data configuration example of positioning history data.

FIG. 6 is a view showing an example of data stored in a ROM.

FIG. 7 is a view showing an example of data stored in a RAM.

FIG. 8 is a flowchart showing the flow of a GPS positioning process.

FIG. 9 is a flowchart showing the flow of a first GPS positioning process.

FIG. 10 is a flowchart showing the flow of a second GPS positioning process.

FIG. 11 is a flowchart showing the flow of a time correction process.

FIG. 12 is a flowchart showing the flow of a main process.

FIG. 13 is a block diagram showing the configuration of a portable telephone according to a modification.

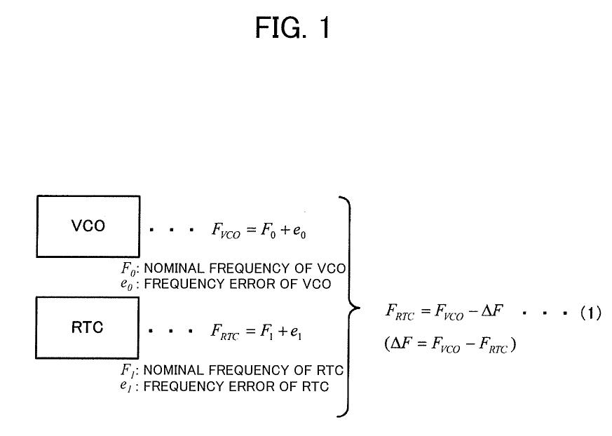

### DESCRIPTION OF EXEMPLARY EMBODIMENTS

According to one embodiment of the invention, there is provided a time information management method comprising:

managing time information using an oscillation signal of a first oscillator and data relating to an actual oscillation frequency of the first oscillator;

calculating an oscillation frequency difference between a second oscillator and the first oscillator; and

estimating the actual oscillation frequency of the first oscillator using the calculated oscillation frequency difference and a nominal frequency of the second oscillator, and updating the data relating to the actual oscillation frequency of the first oscillator.

According to the above configuration, it is possible to manage the time information using the oscillation signal of the first oscillator and the data relating to the actual oscillation frequency of the first oscillator. The oscillation frequency difference between the second oscillator and the first oscillator is calculated. The actual oscillation frequency of the first oscillator is estimated using the oscillation frequency difference and the nominal frequency of the second oscillator, and the above data is updated. Therefore, the time information can be appropriately managed without requiring an external device such as a server by forming an electronic instrument in which the first oscillator and the second oscillator are provided in a single housing, for example.

According to another embodiment of the invention, there is provide a time information management method for an electronic circuit in a sleep mode, the electronic circuit including a measurement section that measures a current time and a current position based on a satellite signal from a positioning satellite, and operating in a plurality of operation modes including the sleep mode, an operation of the measurement section being suspended in the sleep mode, the method comprising:

managing time information using an oscillation signal of a first oscillator and data relating to an actual oscillation frequency of the first oscillator;

calculating an oscillation frequency difference between a second oscillator and the first oscillator; and

estimating the actual oscillation frequency of the first oscillator using the calculated oscillation frequency difference and a nominal frequency of the second oscillator, and updating the data relating to the actual oscillation frequency of the first oscillator.

According to this configuration, it is possible for the electronic circuit that operates in a plurality of operation modes including the sleep mode to calculate the oscillation frequency difference between the first oscillator and the second oscillator, and to estimate the actual oscillation frequency of the first oscillator using the oscillation frequency difference and the nominal frequency of the second oscillator.

In the time information management method,

the second oscillator may be an oscillator that has a frequency accuracy higher than that of the first oscillator.

According to this configuration, as the frequency accuracy of the second oscillator is higher than that of the first oscillator, it is possible to estimate the actual frequency of the first oscillator with greater accuracy.

In the time information management method,

the actual oscillation frequency of the first oscillator may be estimated when a time elapsed from preceding estimation has satisfied a given elapsed time condition, and the data relating to the actual oscillation frequency of the first oscillator may be then updated.

According to this configuration, it is possible to estimate the actual oscillation frequency of the first oscillator when the time elapsed from the preceding estimation has reached a given time, for example.

The time information management method may further comprise:

detecting an operation environment event value including at least temperature,

the actual oscillation frequency of the first oscillator may be estimated when a change in the detected operation environment event value has satisfied an event value state condition that is determined in advance as a state in which the actual oscillation frequency of the first oscillator should be estimated, and the data relating to the actual oscillation frequency of the first oscillator may be then updated.

According to this configuration, it is possible to estimate the actual oscillation frequency of the first oscillator when the difference between the temperature detected last time and the current temperature has become equal to or larger than a given temperature difference, for example.

In the time information management method,

the second oscillator may be an oscillator that can be changed in oscillation frequency, the oscillation frequency of the second oscillator being adjusted by an adjustment section at a given timing; and

the actual oscillation frequency of the first oscillator may be estimated when the oscillation frequency of the second oscillator has been adjusted by the adjustment section, and the data relating to the actual oscillation frequency of the first oscillator may be then updated.

According to this configuration, it is possible to estimate the actual oscillation frequency of the first oscillator when the oscillation frequency of the second oscillator has been adjusted.

In the time information management method,

the second oscillator may be an oscillator that can be changed in oscillation frequency and provided in a wireless communication circuit that implements frequency synchronization with a communication target by changing the oscillation frequency of the second oscillator to perform wireless communication; and

the actual oscillation frequency of the first oscillator may be estimated when the wireless communication circuit has performed the wireless communication, and the data relating to the actual oscillation frequency of the first oscillator may be then updated.

According to this configuration, the second oscillator is provided in the wireless communication circuit that performs wireless communication, and it is possible to estimate the actual oscillation frequency of the first oscillator when the wireless communication circuit has performed the wireless communication.

According to anther embodiment of the invention, there is provided an electronic instrument comprising an electronic circuit, a control circuit, a first oscillator, and a second oscillator,

the electronic circuit including:

a time information management section that manages time information using an oscillation signal of the first oscillator and data relating to an actual oscillation frequency of the first oscillator;

a frequency difference calculation section that calculates an oscillation frequency difference between the first oscillator and the second oscillator; and

an estimation section that estimates the actual oscillation frequency of the first oscillator using the oscillation frequency difference calculated by the frequency difference calculation section and a nominal frequency of the second oscillator, and updates the data relating to the actual oscillation frequency of the first oscillator; and

the control circuit including an estimation execution control section that controls execution of the estimation by the estimation section.

According to this configuration, the electronic circuit manages the time information using the oscillation signal of the first oscillator and the data relating to the actual oscillation frequency of the first oscillator. The oscillation frequency difference between the first oscillator and the second oscillator is calculated, and the estimation section estimates the actual oscillation frequency of the first oscillator using the oscillation frequency difference and the nominal frequency of the second oscillator. The control circuit controls execution of estimation of the actual oscillation frequency of the first oscillator by the estimation section. Therefore, the same effects as in the above embodiments can be achieved.

In the electronic instrument,

the electronic circuit may include a measurement section that measures a current time and a current position based on a satellite signal from a positioning satellite, and may operate in a plurality of operation modes including a sleep mode, an operation of the measurement section may be suspended in the sleep mode;

the control circuit may control the operation mode of the electronic circuit;

the time information management section may manage information relating to the current time in the sleep mode using the oscillation signal of the first oscillator and the data relating to the actual oscillation frequency of the first oscillator; and

the estimation execution control section may control execution of the estimation by the estimation section in the sleep mode.

According to this configuration, the electronic circuit measures the current time and the current position using the measurement section based on the satellite signal from the positioning satellite. The electronic circuit operates in a plurality of operation modes including the sleep mode in which the operation of the measurement section is suspended, and the operation mode of the electronic circuit is controlled by the control circuit. The estimation execution control section controls execution of estimation of the actual oscillation frequency of the first oscillator by the estimation section in the sleep mode.

In the electronic instrument,

the second oscillator may be an oscillator that can be changed in oscillation frequency;

the electronic instrument may further comprise a wireless communication circuit that implements frequency synchronization with a communication target by changing the oscillation frequency of the second oscillator to perform wireless communication, the wireless communication circuit including the second oscillator;

the control circuit may further include a wireless communication execution control section that controls execution of the wireless communication by the wireless communication circuit; and

the estimation execution control section may cause the estimation section to estimate the actual oscillation frequency of the first oscillator when the wireless communication circuit has performed the wireless communication.

According to this configuration, the second oscillator is provided in the wireless communication circuit that performs wireless communication, and the estimation section estimates the actual oscillation frequency of the first oscillator when the wireless communication circuit has performed the wireless communication.

In the electronic instrument,

the second oscillator may be an oscillator that has a frequency accuracy higher than that of the first oscillator.

According to this configuration, as the frequency accuracy of the second oscillator is higher than that of the first oscillator, the accuracy of estimate of the actual frequency of the first oscillator by the estimation section is improved.

Embodiments of the invention are described below with reference to the drawings. Note that the following embodiments do not in any way limit the scope of the invention laid out in the claims. Note that all elements of the following embodiments should not necessarily be taken as essential requirements for the invention.

An embodiment in which the invention is applied to a portable telephone that is one type of electronic instrument including a global positioning system (GPS) satellite signal receiver device is described below with reference to the drawings.

1. Principle

The principle of estimating the actual frequency of a first oscillator that is a characteristic process according to this embodiment is described below. A portable telephone 1 includes a voltage-controlled oscillator (VCO) (i.e., second oscillator) of which the oscillation frequency is controlled by a control voltage, and a real-time clock (RTC) (i.e., first oscillator) used to keep time, generate an operation clock signal, or the like.

When the nominal frequency of the VCO is referred to as F₀ and the frequency error of the VCO is referred to as e₀, the actual oscillation frequency F_{VCO} of the VCO is given by F₀+e₀. When the nominal frequency of the RTC is referred to as F₁ and the frequency error of the RTC is referred to as e₁, the actual oscillation frequency of the RTC is given by F₁+e₁. The frequency error e₀ of the VCO is as small as about 0.1 ppm. On the other hand, the frequency error of the RTC is as large as about 50 ppm. Note that 1 ppm corresponds to a clock error of about 10⁻⁶ seconds per second.

Since the accuracy of time information is very important for GPS positioning, the located position undergoes a large positioning error when positioning calculations are performed using time information based on the oscillation signal of the RTC having a very large frequency error (i.e., 50 ppm). In this embodiment, the current actual frequency of the RTC (hereinafter referred to as “RTC actual frequency”) is estimated using the oscillation frequency difference between the oscillation frequency of the VCO and the oscillation frequency of the RTC and the oscillation frequency (nominal frequency) of the VCO.

Specifically, the RTC actual frequency can be calculated according to the following expression (1) using the oscillation frequency difference ΔF between the oscillation frequency F_{VCO} of the VCO and the oscillation frequency F_{RTC} of the RTC and the oscillation frequency F_{VCO} of the VCO.

F_{RTC}=F_{VCO}−ΔF (1)

where, ΔF=F_{VCO}−F_{RTC}.

2. Functional Configuration

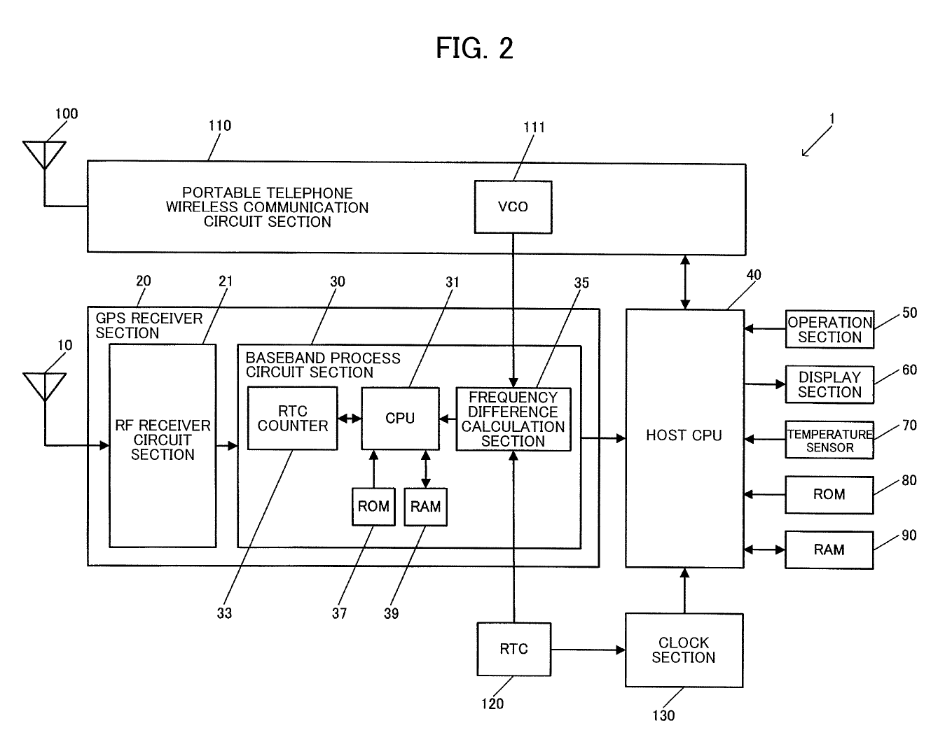

FIG. 2 is a block diagram showing the functional configuration of the portable telephone 1. The portable telephone 1 includes a GPS antenna 10, a GPS receiver section 20, a host central processing unit (CPU) 40, an operation section 50, a display section 60, a temperature sensor 70, a read-only memory (ROM) 80, a random access memory (RAM) 90, a portable telephone antenna 100, a portable telephone wireless communication circuit section 110, an RTC 120, and a clock section 130.

The GPS antenna 10 receives an RF signal including a GPS satellite signal transmitted from a GPS satellite, and outputs the received signal to the GPS receiver section 20. The GPS satellite signal is a spread spectrum modulated signal called a coarse and acquisition (C/A) code. The GPS satellite signal is superimposed on a carrier in an L1 band (carrier frequency: 1.57542 GHz).

The GPS receiver section 20 is a positioning section that locates the current position of the portable telephone 1 based on the signal output from the GPS antenna 10. The GPS receiver section 20 is a functional block corresponding to a GPS receiver. The GPS receiver section 20 includes a radio frequency (RF) receiver circuit section 21 and a baseband process circuit section 30. The RF receiver circuit section 21 and the baseband process circuit section 30 may be produced as different large scale integrated (LSI) circuits, or may be incorporated in one chip.

The RF receiver circuit section 21 is a high-frequency signal (RF signal) circuit block. The RF receiver circuit section 21 generates an RF signal multiplication oscillation signal by dividing or multiplying the frequency of a given oscillation signal. The RF receiver circuit section 21 down-converts the RF signal into an intermediate-frequency signal (hereinafter referred to as “IF signal”) by multiplying the RF signal output from the GPS antenna 10 by the generated oscillation signal, subjecting the IF signal to amplification and the like, converts the resulting signal into a digital signal using an A/D converter, and outputs the digital signal to the baseband process circuit section 30.

The baseband process circuit section 30 is a circuit section that acquires/extracts the GPS satellite signal by performing a correlation detection process and the like on the IF signal output from the RF receiver circuit section 21, decodes data contained in the GPS satellite signal to extract a navigation message, time information, and the like, and performs positioning calculations. In this embodiment, the baseband process circuit section 30 functions as a time information management system that manages time information.

The baseband process circuit section 30 includes a circuit that performs a correlation process, a circuit that generates a spread code (code replica) for performing the correlation process, a circuit that decodes data, a CPU 31 that is a processor that controls each section of the baseband process circuit section 30 and the RF reception circuit section 21 and performs various calculations, an RTC counter 33, a frequency difference calculation section 35, a ROM 37, and a RAM 39.

The RTC counter 33 increments the counter value by one in one clock cycle in synchronization with a clock signal output from the RTC 120, for example. The RTC counter 33 outputs the counter value to the CPU 31. The RTC counter 33 is controlled by the host CPU 40 so that the RTC counter 33 operates on a battery in a mode in which the operation of the GPS receiver section 20 is suspended (hereinafter referred to as “sleep mode”).

The frequency difference calculation section 35 is a circuit section that calculates the oscillation frequency difference ΔF (=F_{VCO}−F_{RTC}) between the oscillation frequency F_{VCO} of the VCO 111 and the oscillation frequency F_{RTC} of the RTC 120 based on an oscillation signal input from the VCO 111 (hereinafter referred to as “VCO oscillation signal”) and an oscillation signal input from the RTC 120 (hereinafter referred to as “RTC oscillation signal”). The frequency difference calculation section 35 outputs the calculation result to the CPU 31.

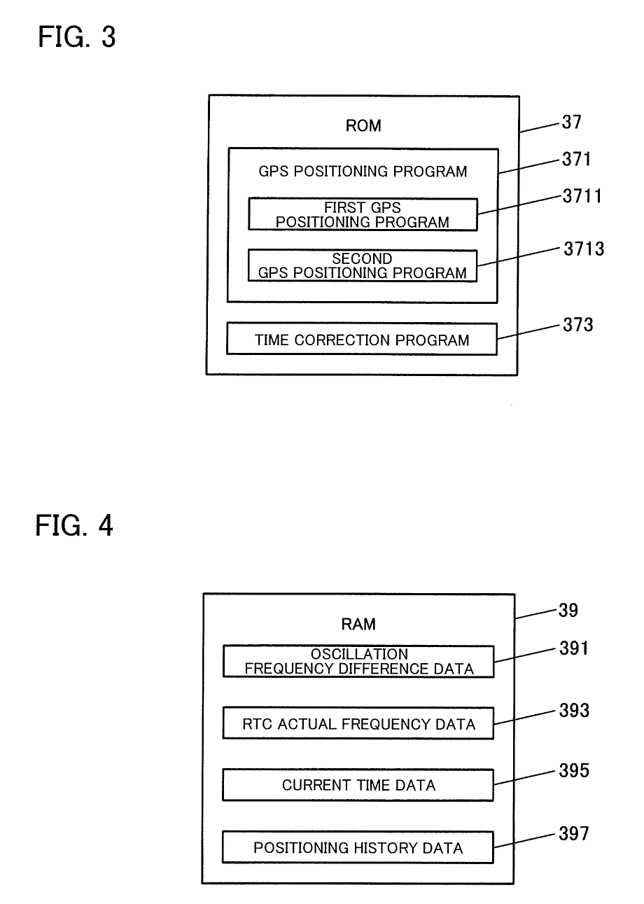

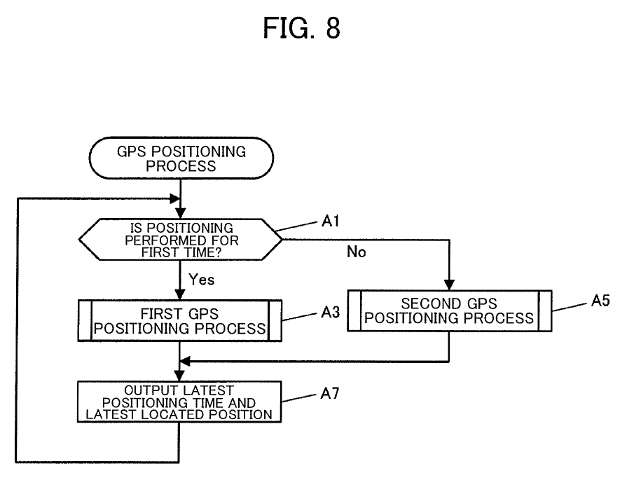

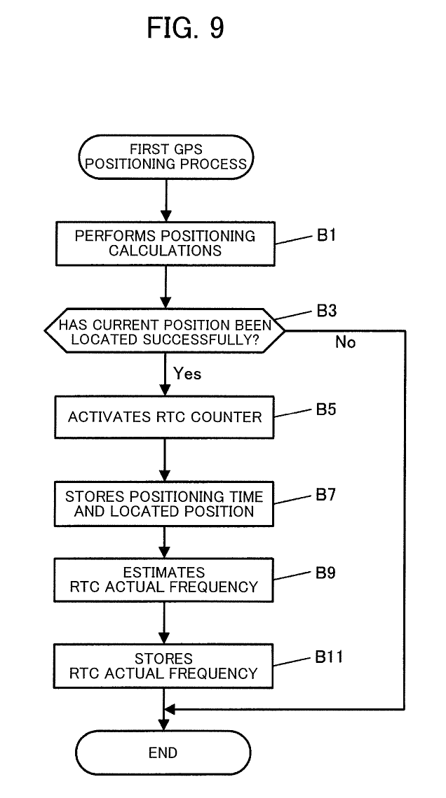

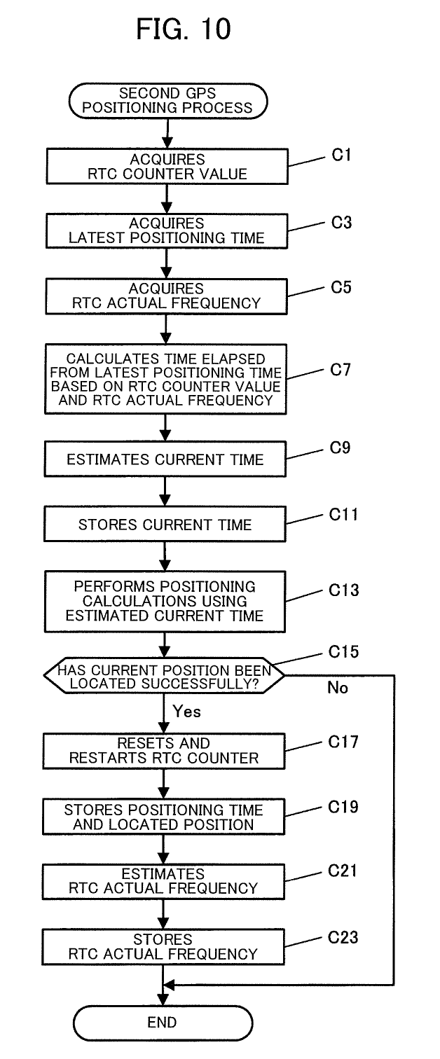

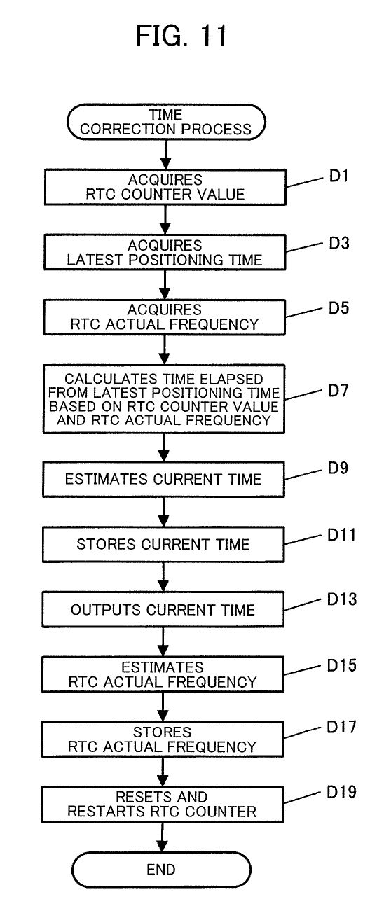

FIG. 3 is a view showing an example of data stored in the ROM 37. The ROM 37 stores a GPS positioning program 371 that is read by the CPU 31 and executed as a GPS positioning process (see FIG. 8), and a time correction program 373 executed as a time correction process (see FIG. 11). The GPS positioning program 371 includes a first GPS positioning program 3711 executed as a first GPS positioning process (see FIG. 9) and a second GPS positioning program 3713 executed as a second GPS positioning process (see FIG. 10) as subroutines.

The GPS positioning process is executed by the CPU 31 when the host CPU 40 has issued a positioning execution instruction. Specifically, the CPU 31 executes the first GPS positioning process to locate the current position of the portable telephone 1 in the first positioning after the GPS receiver section 20 has been activated, executes the second GPS positioning process in the second or subsequent positioning to locate the current position of the portable telephone 1, and outputs the positioning result to the host CPU 40. The details of the GPS positioning process are described later using a flowchart.

In the first GPS positioning process, the CPU 31 performs positioning calculations using time information and the like included in positioning assist information acquired by the portable telephone wireless communication circuit section 110 via communication with a base station to locate the current position of the portable telephone 1. The positioning assist information is information provided from a given server through a portable phone network. The positioning assist information is known as assist information used for the assist GPS. The positioning assist information includes time information, satellite orbit information, position information relating to a base station with which the portable telephone communicates, and the like. The portable telephone 1 acquires the positioning assist information from a base station as assist information used when performing positioning calculations.

When the current position of the portable telephone 1 has been located successfully, the CPU 31 activates the RTC counter 33, estimates the RTC actual frequency according to the expression (1) using the oscillation frequency V_{VCO} of the VCO 111 and the oscillation frequency difference ΔF calculated by the frequency difference calculation section 35, and updates RTC actual frequency data 393 stored in the RAM 39. The details of the first GPS positioning process are described later using a flowchart.

In the second GPS positioning process, the CPU 31 estimates the current time by calculating the time elapsed from the latest positioning time based on the current counter value of the RTC counter 33 and the RTC actual frequency, and updates current time data 395 stored in the RAM 39. The CPU 31 performs positioning calculations using the estimated current time information. When the current position of the portable telephone 1 has been located successfully, the CPU 31 estimates the RTC actual frequency according to the expression (1), and updates the RTC actual frequency data 393 stored in the RAM 39. The details of the second GPS positioning process are described later using a flowchart.

The time correction process is executed by the CPU 31 when the host CPU 40 has issued a time correction execution instruction. Specifically, the CPU 31 estimates the current time by calculating the time elapsed from the latest positioning time based on the current counter value of the RTC counter 33 and the RTC actual frequency, and updates the current time data 395 stored in the RAM 39. The details of the time correction process are described later using a flowchart.

FIG. 4 is a view showing an example of data stored in the RAM 39. The RAM 39 stores oscillation frequency difference data 391, the RTC actual frequency data 393, the current time data 395, and positioning history data 397.

The oscillation frequency difference ΔF between the oscillation frequency F_{VCO} of the VCO 111 and the oscillation frequency F_{RTC} of the RTC 120 is stored as the oscillation frequency difference data 391. The CPU 31 updates the oscillation frequency difference data 391 with the oscillation frequency difference ΔF calculated by the frequency difference calculation section 35.

The RTC actual frequency estimated by the CPU 31 in the GPS positioning process or the time correction process is stored as the RTC actual frequency data 393. The current time estimated by the CPU 31 in the GPS positioning process or the time correction process is stored as the current time data 395.

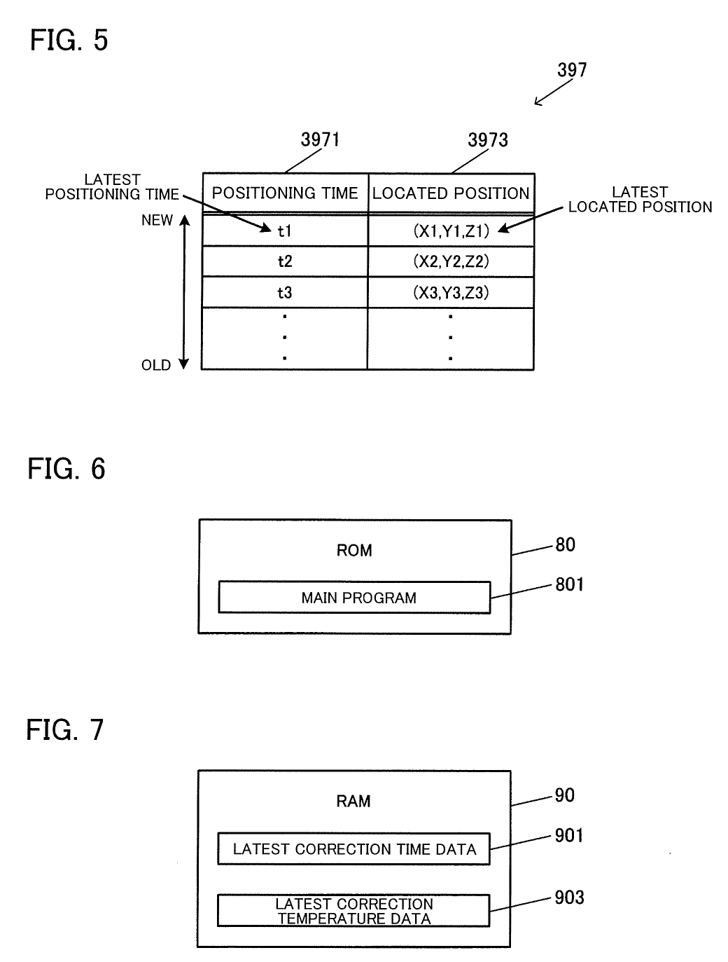

FIG. 5 is a view showing a data configuration example of the positioning history data 397. A positioning time 3971 (i.e., time when positioning is performed) and a located position 3973 are stored as the positioning history data 397 while being associated with each other in reverse chronological order. The positioning time 3971 that is the latest is referred to as “latest positioning time”, and the located position 3973 that is the latest is referred to as “latest located position”. In FIG. 5, the latest positioning time is t1, and the latest located position is (X1, Y1, Z1). The positioning history data 397 is updated by the CPU 31 in the GPS positioning process.

The host CPU 40 is a processor that controls each section of the portable telephone 1 based on various programs such as a system program stored in the ROM 80. The host CPU 40 causes the display section 60 to display a navigation screen in which the latest located position input from the CPU 31 is plotted.

The operation section 50 is an input device including a touch panel, a button switch, or the like, and outputs a signal that indicates a key or a button that has been pressed to the host CPU 40. Various instruction inputs such as a telephone call request or an e-mail send/receive request are performed by operating the operation section 50.

The display section 60 is a display device that includes a liquid crystal display (LCD) or the like, and displays various images based on a display signal input from the host CPU 40. The display section 60 displays the navigation screen, the time information, and the like.

The temperature sensor 70 is a contact or contactless temperature sensor that measures the ambient temperature at given intervals (e.g., every second). The temperature sensor 70 outputs the measurement result to the host CPU 40.

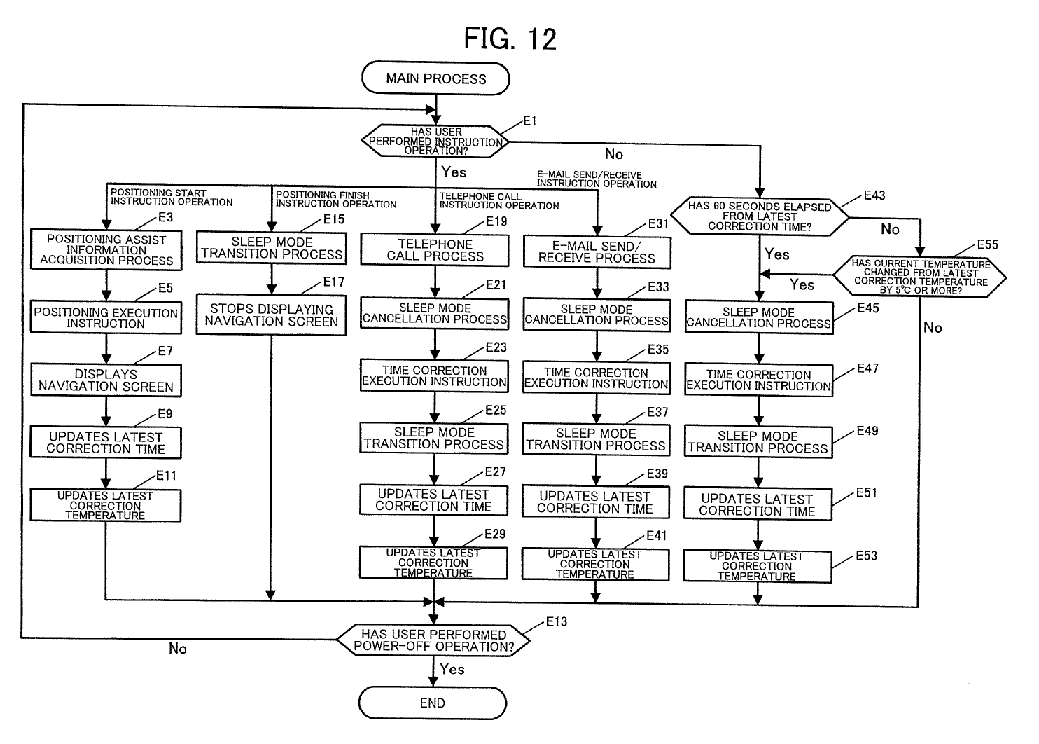

FIG. 6 is a view showing an example of data stored in the ROM 80. The ROM 80 stores a main program 801 that is read by the host CPU 40 and executed as a main process (see FIG. 12).

In the main process, when the user has performed an instruction operation using the operation section 50, the host CPU 40 implements startup/stop of the GPS receiver section 20, a telephone call, an e-mail send/receive process, and the like according to the instruction operation. The host CPU 40 issues the time correction execution instruction to the CPU 31 when a given time correction condition has been satisfied so that the CPU 31 executes the time correction process. The details of the main process are described later using a flowchart.

FIG. 7 is a view showing an example of data stored in the RAM 90. The RAM 90 stores latest correction time data 901 and latest correction temperature data 903.

The latest positioning time calculated by the GPS positioning process executed by the CPU 31 or the current time estimated by the time correction process is stored as the latest correction time data 901 as the latest correction time. The latest correction time data 901 is updated by the host CPU 40 in the main process.

The temperature input from the temperature sensor 70 when the latest correction time is updated is stored as the latest correction temperature data 903 as the latest correction temperature. The latest correction temperature data 903 is updated by the host CPU 40 in the main process.

The portable telephone antenna 100 is an antenna that transmits and receives a portable telephone radio signal between the portable telephone 1 and a base station installed by a communication service provider of the portable telephone 1.

The portable telephone wireless communication circuit section 110 is a portable telephone communication circuit section that includes an RF conversion circuit, a baseband process circuit, and the like. The portable telephone wireless communication circuit section 110 implements a telephone call, an e-mail send/receive process, or the like by modulating/demodulating the portable telephone radio signal, for example. In this embodiment, the portable telephone wireless communication circuit section 110 includes the VCO 111. The portable telephone wireless communication circuit section 110 implements frequency synchronization with the base station by changing the oscillation frequency of the VCO 111 using the control voltage to adjust the oscillation frequency of the VCO 111.

Since a constant frequency is used for base station communication, the oscillation frequency of the VCO 111 when frequency synchronization is implemented is a specific frequency. The portable telephone wireless communication circuit section 110 including the VCO 111 is a known circuit section. Therefore, detailed description thereof is omitted. The VCO oscillation signal generated by the VCO 111 is output to the frequency difference calculation section 35. The frequency accuracy of the VCO 111 is significantly higher than the frequency accuracy of the RTC 120.

The RTC 120 is an oscillator that is used to keep time or generate an operation clock signal and generates the oscillation signal (RTC oscillation signal) at a low oscillation frequency (e.g., 32 kHz). In this embodiment, the RTC oscillation signal is output to the clock section 130 for the clock section 130 to keep time, and is also output to the frequency difference calculation section 35. The RTC 120 operates on a battery even when the portable telephone 1 is turned OFF.

The clock section 130 is a clock circuit that keeps the time of the portable telephone 1 based on the RTC oscillation signal output from the RTC 120.

3. Process Flow

FIG. 8 is a flowchart showing the flow of the GPS positioning process of the portable telephone 1 that is executed by causing the CPU 31 to read and execute the GPS positioning program 371 stored in the ROM 37.

The CPU 31 executes the GPS positioning process when the host CPU 40 has issued the positioning execution instruction. The GPS positioning process is executed in a state in which the RF signal is received by the GPS antenna 10 and the RF signal is down-converted into the IF signal by the RF reception circuit section 60, as required.

The CPU 31 determines whether or not positioning is performed for the first time after the GPS receiver section 20 has been activated (step A1). When the CPU 31 has determined that positioning is performed for the first time after the GPS receiver section 20 has been activated (step A1: Yes), the CPU 31 reads and executes the first GPS positioning program 3711 stored in the ROM 37 to execute the first GPS positioning process (step A3).

FIG. 9 is a flowchart showing the flow of the first GPS positioning process.

The CPU 31 performs positioning calculations using a least-square method or the like based on GPS satellite signals received from a plurality of GPS satellites (step B1). In this case, the CPU 31 performs positioning calculations using the time information and the like included in the positioning assist information acquired by the portable telephone wireless communication circuit section 110 via communication with the base station.

The CPU 31 determines whether or not the current position of the portable telephone 1 has been located successfully (step B3). When the CPU 31 has determined that the current position of the portable telephone 1 has not been located successfully (step B3: No), the CPU 31 finishes the first GPS positioning process. When the CPU 31 has determined that the current position of the portable telephone 1 has been located successfully (step B3: Yes), the CPU 31 activates the RTC counter 33 (step B5). The CPU 33 stores the located position 3973 calculated by the positioning calculations in the step B1 in the RAM 39 as the positioning history data 397 corresponding to the positioning time 3971 (step B7).

The CPU 31 then estimates the RTC actual frequency according to the expression (1) using the oscillation frequency difference ΔF calculated by the frequency difference calculation section 35 and the oscillation frequency F_{VCO} of the VCO 111 (step B9). The CPU 31 updates the RTC actual frequency data 393 stored in the RAM 39 with the estimated RTC actual frequency (step B11), and finishes the first GPS positioning process.

Again referring to the GPS positioning process shown in FIG. 8, when the CPU 31 has determined that positioning is not performed for the first time after the GPS receiver section 20 has been activated in the step A1 (step A1: No), the CPU 31 reads and executes the second GPS positioning program 3713 stored in the ROM 37 to execute the second GPS positioning process (step A5).

FIG. 10 is a flowchart showing the flow of the second GPS positioning process.

The CPU 31 acquires the counter value from the RTC counter 33 (step C1). The CPU 31 acquires the latest positioning time from the positioning history data 397 stored in the RAM 39 (step C3), and acquires the RTC actual frequency from the RTC actual frequency data 393 (step C5).

The CPU 31 then calculates the time elapsed from the latest positioning time acquired in the step C3 based on the RTC counter value acquired in the step C1 and the RTC actual frequency acquired in the step C5 (step C7). Since the counter value of the RTC counter 33 is incremented by one in one clock cycle, the elapsed time can be calculated by dividing the counter value by the RTC actual frequency.

The CPU 31 then estimates the time obtained by adding the elapsed time calculated in the step C7 to the latest positioning time to be the current time (step C9), and updates the current time data 395 stored in the RAM 39 (step C11). The CPU 31 then performs positioning calculations using a least-square method or the like based on GPS satellite signals received from a plurality of GPS satellites (step C13). In this case, the CPU 31 performs positioning calculations using the current time estimated in the step C9.

The CPU 31 determines whether or not the current position of the portable telephone 1 has been located successfully (step C15). When the CPU 31 has determined that the current position of the portable telephone 1 has not been located successfully (step C15: No), the CPU 31 finishes the second GPS positioning process. When the CPU 31 has determined that the current position of the portable telephone 1 has been located successfully (step C15: Yes), the CPU 31 resets and restarts the RTC counter 33 (step C17), and stores the located position 3973 calculated by the positioning calculations in the step C13 in the RAM 39 as the positioning history data 397 corresponding to the positioning time 3971 (step C19).

The CPU 31 then estimates the RTC actual frequency according to the expression (1) using the oscillation frequency difference ΔF calculated by the frequency difference calculation section 35 and the oscillation frequency F_{VCO} of the VCO 111 (step C21). The CPU 31 updates the RTC actual frequency data 393 stored in the RAM 39 with the estimated RTC actual frequency (step C23), and finishes the second GPS positioning process.

Again referring to the GPS positioning process shown in FIG. 8, after the first GPS positioning process or the second GPS positioning process has been completed, the CPU 31 outputs the latest positioning time and the latest located position stored in the RAM 39 as the positioning history data 397 to the host CPU 40 (step A7), and returns to the step A1.

FIG. 11 is a flowchart showing the flow of the time correction process of the portable telephone 1 that is executed by causing the CPU 31 to read and execute the time correction program 373 stored in the ROM 37. The CPU 31 executes the time correction process when the host CPU 40 has issued the time correction execution instruction.

The CPU 31 performs the process in steps D1 to D11 to estimate the current time, and updates the current time data 395 stored in the RAM 39. The process in the steps D1 to D11 is the same as the process in the steps C1 to C11 of the second GPS positioning process.

The CPU 31 then outputs the estimated current time to the host CPU 40 (step D13). The CPU 31 then estimates the RTC actual frequency according to the expression (1) using the oscillation frequency F_{VCO} of the VCO 111 and the oscillation frequency difference ΔF calculated by the frequency difference calculation section 35 (step D15). The CPU 31 then updates the RTC actual frequency data 393 stored in the RAM 39 with the estimated RTC actual frequency (step D17), resets and restarts the RTC counter 33 (step D19), and finishes the time correction process.

FIG. 12 is a flowchart showing the flow of the main process of the portable telephone 1 that is executed by causing the host CPU 40 to read and execute the main program 801 stored in the ROM 80.

The host CPU 40 determines whether or not the user has performed an instruction operation using the operation section 50 (step E1). When the host CPU 40 has determined that the user has performed a positioning start instruction operation (step E1: Yes, positioning start instruction operation), the host CPU 40 executes a positioning assist information acquisition process (step E3). Specifically, the host CPU 40 activates the portable telephone wireless communication circuit section 110, and causes the portable telephone wireless communication circuit section 110 to communicate with the base station and acquire the positioning assist information used for positioning calculations. In this case, the portable telephone wireless communication circuit section 110 activates the VCO 111 for communication with the base station, and implements frequency synchronization with the base station.

The host CPU 40 then issues the positioning execution instruction to the CPU 31 so that the CPU 31 starts the GPS positioning process (step E5). The host CPU 40 causes the display section 60 to display a navigation screen in which the latest located position output from the CPU 31 at given intervals is plotted (step E7).

The host CPU 40 updates the latest correction time data 901 stored in the RAM 90 with the latest positioning time (latest correction time) output from the CPU 31 at given intervals (step E9), and updates the latest correction temperature data 903 stored in the RAM 90 with the current temperature (latest correction temperature) input from the temperature sensor 70 (step E11).

The host CPU 40 determines whether or not the user has performed a power-OFF operation using the operation section 50 (step E13). When the host CPU 40 has determined that the user has not performed the power-OFF operation (step E13: No), the host CPU 40 returns to the step E1. When the host CPU 40 has determined that the user has performed the power-OFF operation of the portable telephone 1 (step E13: Yes), the host CPU 40 finishes the main process.

When the host CPU 40 has determined that the user has performed a positioning finish instruction operation in the step E1 (step E1: Yes, positioning finish instruction operation), the host CPU 40 performs a sleep mode transition process so that the GPS receiver section 20 stops operation and transitions to the sleep mode (step E15). In this case, the host CPU 40 does not stop the operation of the RTC counter 33. The host CPU 40 then causes the display section 60 to stop displaying the navigation screen (step E17), and transitions to the step E13.

When the host CPU 40 has determined that the user has performed a telephone call instruction operation in the step E1 (step E1: Yes, telephone call instruction operation), the host CPU 40 performs a telephone call process (step E19). Specifically, the host CPU 40 instructs the portable telephone wireless communication circuit section 110 to communicate with the base station to implement a telephone call between the portable telephone 1 and another portable telephone. In this case, the portable telephone wireless communication circuit section 110 adjusts the oscillation frequency of the VCO 111 in order to implement frequency synchronization with the base station.

The host CPU 40 then performs a sleep mode cancellation process to activate the baseband process circuit section 30 (step E21), and issues the time correction execution instruction to the CPU 31 so that the CPU 31 executes the time correction process (step E23). After the time correction process has been completed, the host CPU 40 performs the sleep mode transition process so that the baseband process circuit section 30 transitions to the sleep mode (step E25).

The host CPU 40 then updates the latest correction time data 901 stored in the RAM 90 with the current time input from the CPU 31 (step E27), and updates the latest correction temperature data 903 stored in the RAM 90 with the current temperature (latest correction temperature) input from the temperature sensor 70 (step E29). The host CPU 40 then transitions to the step E13.

When the host CPU 40 has determined that the user has issued an e-mail send/receive request in the step E1 (step E1: Yes, e-mail send/receive request), the host CPU 40 performs an e-mail send/receive process (step E31). Specifically, the host CPU 40 instructs the portable telephone wireless communication circuit section 110 to communicate with the base station to implement the e-mail send/receive process between the portable telephone 1 and another portable telephone. In this case, the portable telephone wireless communication circuit section 110 adjusts the oscillation frequency of the VCO 111 in order to implement frequency synchronization with the base station.

The host CPU 40 then performs the sleep mode cancellation process, issues the time correction execution instruction, performs the sleep mode transition process, updates the latest correction time, updates the latest correction temperature in the same manner as in the steps E21 to E29 (steps E3 3 to E41), and transitions to the step E13.

When the host CPU 40 has determined that the user has not performed an instruction operation in the step E1 (step E1: No), the host CPU 40 determines whether or not 60 seconds has elapsed from the latest correction time that is stored in the RAM 90 as the latest correction time data 901 (step E43).

When the host CPU 40 has determined that 60 seconds has elapsed from the latest correction time (step E43: Yes), the host CPU 40 performs the sleep mode cancellation process, issues the time correction execution instruction, performs the sleep mode transition process, updates the latest correction time, updates the latest correction temperature in the same manner as in the steps E21 to E29 (steps E45 to E53), and transitions to the step E13.

When the host CPU 40 has determined that 60 seconds has not elapsed from the latest correction time in the step E43 (step E43: No), the host CPU 40 determines whether or not the current temperature has changed from the latest correction temperature stored in the RAM 90 (i.e., latest correction temperature data 903) by 5° C. or more (step E55). When the host CPU 40 has determined that the current temperature has changed from the latest correction temperature by 5° C. or more (step E55: Yes), the host CPU 40 transitions to the step E45. When the host CPU 40 has determined that the current temperature has not changed from the latest correction temperature by 5° C. or more (step E55: No), the host CPU 40 transitions to the step E13.

4. Effects

According to this embodiment, the baseband process circuit section 30 (i.e., time information management system) manages the time information using the oscillation signal of the RTC 120 (first oscillator) and the data relating to the current actual frequency of the RTC 120. The oscillation frequency difference between the VCO 111 (second oscillator) of which the frequency accuracy is higher than that of the RTC 120 and the RTC 120 is calculated. The current actual frequency of the RTC 120 is estimated using the oscillation frequency difference and the oscillation frequency (nominal frequency) of the VCO 111, and the RTC actual frequency data 393 is updated. Since the portable telephone 1 is configured so that the RTC 120 and the VCO 111 are provided in a single housing, the time information can be appropriately corrected and managed without requiring an external device such as a server.

5. Modification

5.1 Electronic Instrument

The invention may be applied to an arbitrary electronic instrument including an electronic circuit that estimates the RTC actual frequency and manages the time information and a control circuit that controls the RTC actual frequency estimation of the electronic circuit. For example, the invention may be applied to a notebook personal computer, a personal digital assistant (PDA), a car navigation system, and the like.

5.2 Satellite Positioning System

The above embodiments have been described taking the GPS as an example of the satellite positioning system. Note that the invention may also be applied to other satellite positioning systems such as the wide area augmentation system (WAAS), the Quasi Zenith Satellite System (QZSS), the Global Navigation Satellite System (GLONASS), and the GALILEO.

5.3 Process Split

The host CPU 40 may perform some or the entirety of the process performed by the CPU 31. For example, the CPU 31 may decode the navigation message, the time information, and the like superimposed on the acquired GPS satellite signal, and output the navigation message, the time information, and the like to the host CPU 40. The host CPU 40 may perform the GPS positioning process and the time correction process using these pieces of information to estimate the RTC actual frequency and the current time.

5.4 First Oscillator and Second Oscillator

The above embodiments have been described taking an example in which the first oscillator is the RTC and the second oscillator is the VCO. Note that the first oscillator and the second oscillator may be other oscillators. For example, a temperature-compensated crystal oscillator (TCXO), a voltage-controlled crystal oscillator (VCXO), or the like may be used instead of the RTC, and a digital local oscillator (DLO), a numerical controlled oscillator (NCO), or the like may be used instead of the VCO. Arbitrary oscillators may be used in combination insofar as the frequency accuracy of the second oscillator is higher than that of the first oscillator.

5.5 Time Information Management System

The above embodiments have been described taking an example in which the baseband process circuit section 30 functions as the time information management system. Note that the clock section 130 may be used as the time information management system.

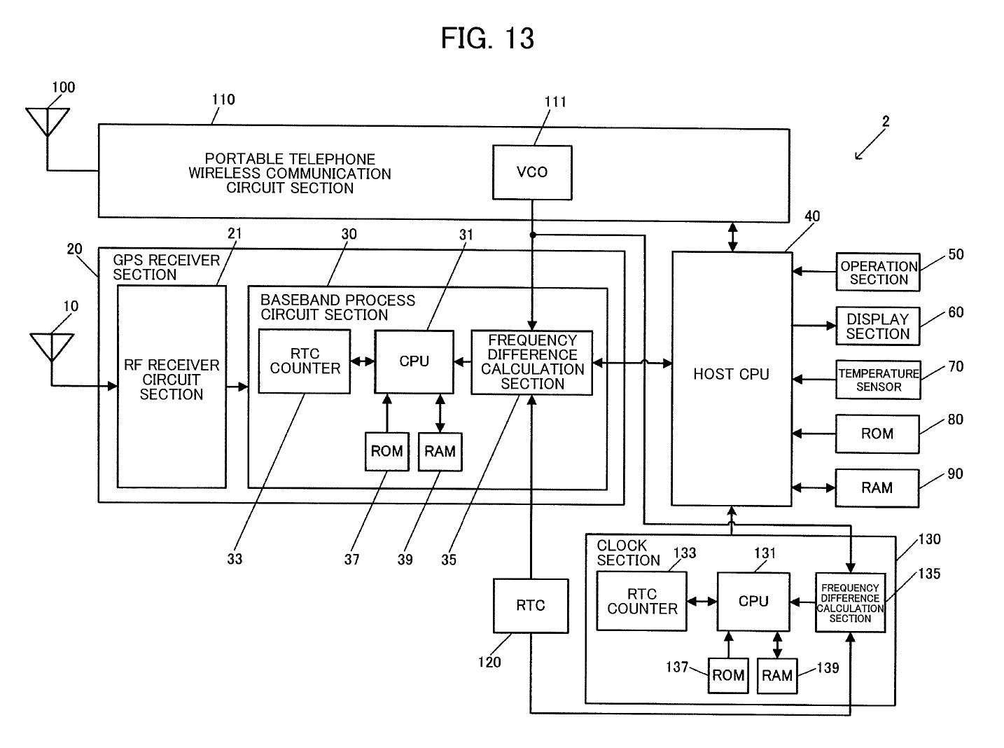

FIG. 13 is a block diagram showing the functional configuration of a portable telephone 2 when the clock section 130 is used as the time information management system. The same elements as the elements of the portable telephone 1 are indicated by the same symbols. Description of these elements is omitted. In the portable telephone 2, the clock section 130 includes a CPU 131, an RTC counter 133, a frequency difference calculation section 135, a ROM 137, and a RAM 139. The VCO oscillation signal from the VCO 111 and the RTC oscillation signal from the RTC 120 are input to the frequency difference calculation section 135.

The CPU 131 estimates the RTC actual frequency according to the expression (1) using the oscillation frequency difference ΔF between the oscillation frequency V_{VCO} of the VCO 111 and the oscillation frequency V_{RTC} of the RTC 120 calculated by the frequency difference calculation section 135, and the oscillation frequency V_{VCO} of the VCO 111. The CPU 131 updates the RTC actual frequency data 393 stored in the RAM 39 with the estimated RTC actual frequency. The CPU 131 estimates the current time based on the estimated RTC actual frequency and the counter value of the RTC counter 133, and updates the current time data stored in the RAM 139. According to the configuration shown in FIG. 13, the accuracy of the current time kept by the clock section 130 can be improved.

5.6 Estimation Execution Control Section

The above embodiments have been described taking an example in which the host CPU 40 controls the CPU 31 to estimate the RTC actual frequency and the time information. Specifically, the host CPU 40 determines whether or not a given time has elapsed from the latest correction time and determines whether or not the current temperature has changed from the latest correction temperature by a value equal to or larger than a given temperature, for example, and causes the CPU 31 to execute the time correction process based on the determination results.

Note that the CPU 31 may be caused to function as an estimation execution control section. Specifically, the CPU 31 may determine the elapsed time and a change in temperature, and execute the time correction process based on the determination results.

5.7 Detection of Operation Environment Event Value

The above embodiments have been described taking an example in which the current time is corrected when the current temperature measured by the temperature sensor 70 has changed from the latest correction temperature by a value equal to or larger than a given temperature (e.g., 5° C.). Note that an optical (illuminance) sensor may be provided, and the current time corrected when the current illuminance measured by the optical sensor has changed from the latest correction illuminance (illuminance during the latest correction) by a value equal to or larger than a given illuminance (e.g., 1000 lx). Alternatively, an acceleration sensor is provided to detect the acceleration of the portable telephone 1.

Although only some embodiments of the invention have been described in detail above, those skilled in the art would readily appreciate that many modifications are possible in the embodiments without materially departing from the novel teachings and advantages of the invention. Accordingly, such modifications are intended to be included within the scope of the invention.

What is claimed is:

1. A time information management method comprising:
managing time information using an oscillation signal of a first oscillator and data relating to an actual oscillation frequency of the first oscillator;
calculating an oscillation frequency difference between a second oscillator and the first oscillator; and
estimating the actual oscillation frequency of the first oscillator using the calculated oscillation frequency difference and a nominal frequency of the second oscillator, and updating the data relating to the actual oscillation frequency of the first oscillator.

2. A time information management method for an electronic circuit in a sleep mode, the electronic circuit including a measurement section that measures a current time and a current position based on a satellite signal from a positioning satellite, and operating in a plurality of operation modes including the sleep mode, an operation of the measurement section being suspended in the sleep mode, the method comprising:
managing time information using an oscillation signal of a first oscillator and data relating to an actual oscillation frequency of the first oscillator;
calculating an oscillation frequency difference between a second oscillator and the first oscillator; and
estimating the actual oscillation frequency of the first oscillator using the calculated oscillation frequency difference and a nominal frequency of the second oscillator, and updating the data relating to the actual oscillation frequency of the first oscillator.

3. The time information management method as defined in claim 1, the second oscillator being an oscillator that has a frequency accuracy higher than that of the first oscillator.

4. The time information management method as defined in claim 2,
the second oscillator being an oscillator that has a frequency accuracy higher than that of the first oscillator.

5. The time information management method as defined in claim 1,
the actual oscillation frequency of the first oscillator being estimated when a time elapsed from preceding estimation has satisfied a given elapsed time condition, and the data relating to the actual oscillation frequency of the first oscillator being then updated.

6. The time information management method as defined in claim 1, further comprising:
detecting an operation environment event value including at least temperature,
the actual oscillation frequency of the first oscillator being estimated when a change in the detected operation environment event value has satisfied an event value state condition that is determined in advance as a state in which the actual oscillation frequency of the first oscillator should be estimated, and the data relating to the actual oscillation frequency of the first oscillator being then updated.

7. The time information management method as defined in claim 1,
the second oscillator being an oscillator that can be changed in oscillation frequency, the oscillation frequency of the second oscillator being adjusted by an adjustment section at a given timing; and
the actual oscillation frequency of the first oscillator being estimated when the oscillation frequency of the second oscillator has been adjusted by the adjustment section, and the data relating to the actual oscillation frequency of the first oscillator being then updated.

8. The time information management method as defined in claim 2,
the second oscillator being an oscillator that can be changed in oscillation frequency and provided in a wireless communication circuit that implements frequency synchronization with a communication target by changing the oscillation frequency of the second oscillator to perform wireless communication; and
the actual oscillation frequency of the first oscillator being estimated when the wireless communication circuit has performed the wireless communication, and the data relating to the actual oscillation frequency of the first oscillator being then updated.

9. An electronic instrument comprising an electronic circuit, a control circuit, a first oscillator, and a second oscillator,
the electronic circuit including:
a time information management section that manages time information using an oscillation signal of the first oscillator and data relating to an actual oscillation frequency of the first oscillator;
a frequency difference calculation section that calculates an oscillation frequency difference between the first oscillator and the second oscillator; and
an estimation section that estimates the actual oscillation frequency of the first oscillator using the oscillation frequency difference calculated by the frequency difference calculation section and a nominal frequency of the second oscillator, and updates the data relating to the actual oscillation frequency of the first oscillator; and
the control circuit including an estimation execution control section that controls execution of the estimation by the estimation section.

10. The electronic instrument as defined in claim 9,
the electronic circuit including a measurement section that measures a current time and a current position based on a satellite signal from a positioning satellite, and operating in a plurality of operation modes including a sleep mode, an operation of the measurement section being suspended in the sleep mode;
the control circuit controlling the operation mode of the electronic circuit;
the time information management section managing information relating to the current time in the sleep mode using the oscillation signal of the first oscillator and the data relating to the actual oscillation frequency of the first oscillator; and
the estimation execution control section controlling execution of the estimation by the estimation section in the sleep mode.

11. The electronic instrument as defined in claim 9,
the second oscillator being an oscillator that can be changed in oscillation frequency;
the electronic instrument further comprising a wireless communication circuit that implements frequency synchronization with a communication target by changing the oscillation frequency of the second oscillator to perform wireless communication, the wireless communication circuit including the second oscillator;
the control circuit further including a wireless communication execution control section that controls execution of the wireless communication by the wireless communication circuit; and
the estimation execution control section causing the estimation section to estimate the actual oscillation frequency of the first oscillator when the wireless communication circuit has performed the wireless communication.

12. The electronic instrument as defined in claim 9,
the second oscillator being an oscillator that has a frequency accuracy higher than that of the first oscillator.
